(19) United States
(12) Patent Application Publication
(10) Pub. No.: US 2007/0275265 A1
(43) Pub. Date: Nov. 29, 2007

(54) Organic light emitting layer with a reduced phosphorescent dopant concentration and applications of same

(75) Inventor: Tswen-Hsin Liu, Hsinchu County (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: AU Optronics Corporation, Hsinchu (TW)

(21) Appl. No.: 11/441,365

(22) Filed: May 25, 2006

(51) Int. Cl. H01L 51/54

(52) U.S. Cl. 428/690; 428/917; 313/504; 257/102; 257/103; 257/E51.044; 257/E51.051; 257/E51.043

(57) ABSTRACT

An organic light emitting device having a light emitting layer. The light emitting layer comprises an asymmetrically organometallic chelating complex in the amount of A by weight, a polyamine compound having the chemical formula containing two or more tertiaryamines in the amount of B by weight, and a phosphorescent material in the amount of C by weight, where C is much less than the sum of A and B.

### CROSS-REFERENCE TO RELATED PATENT APPLICATION

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference.

### FIELD OF THE INVENTION

The present invention relates generally to an organic light emitting diode, and more particularly, to an organic light emitting diode device with an organic light emitting layer with a reduced phosphorescent dopant concentration.

### BACKGROUND OF THE INVENTION

Organic light emitting diode (hereinafter “OLED”) devices have drawn great attention in display industries, and particularly in the flat-panel display industry, because it is operable with a low driving voltage and capable of generating light of red, green, and blue colors with high luminance efficiency. These unique attributes are derived from a basic OLED structure comprising of a multilayer stack of thin films of small-molecule organic materials sandwiched between an anode and a cathode.

Generally, an OLED includes a hole-transport layer (hereinafter “HTL”), an electron-transport layer (hereinafter “ETL”), and an electroluminescent layer (hereinafter “EL”) formed therebetween. When an electrical potential difference is applied between the anode and cathode, the injected carriers such as hole at the anode and electron at the cathode migrate towards each other through the HTL and ETL and a fraction of them recombine in the EL to emit light. The intensity of electroluminescence is dependent on the EL medium. Conventionally, the EL medium comprises a carrier host material for recombining the migrated holes and the electrons therein so as to emit light therefrom.

To improve the efficiency of an OLED, a dopant material is usually doped into the carrier host material. The dopant material is selected so as to allow a high level of energy transfer from the carrier host material to the dopant material. For example, U.S. Pat. No. 6,097,147 to Baldo et al. and U.S. Pat. No. 6,303,238 to Thompson et al. disclose an OLED having an EL that includes a charge carrier host material doped with a phosphorescent compound, such as PtOEP. It is understood that for the optimal performance of such an OLED, the concentration rate of the doped phosphorescent compound PtOEP, which is very costly, should be not less than 8% by weight in the EL. Additionally, an exciton blocking layer is formed between the EL and the ETL for preventing holes in the EL from migrating to the cathode.

U.S. Pat. No. 6,645,645 to Adachi et al. discloses an OLED device that include an EL having an electron transporting host material doped with a phosphorescent dopant material, Ir(ppy)₃. It is understood that in the OLED device, no exciton blocking layer is needed. However, in practice, the concentration rate of the doped phosphorescent compound Ir(ppy)₃ still needs to be 6-8% by weight in the EL.

U.S. Pat. No. 6,803,720 to Kwong et al. discloses an improved OLED that has an EL comprising two light emitting materials and one phosphorescent dopant, instead of one light emitting material as described above. It is understood that one of the two light emitting materials is an electron transporting material and the other is a hole transporting material. In one embodiment, the EL has a combination of three materials: (NPB:Alq₃):PtOEP. Among them, NPB is a hole transporting material, Alq₃ is an electron transporting material and PtOEP is phosphorescent dopant material. The use of the two light emitting materials NPB and Alq₃ improves the carrier transporting property of the EL so as to enhance the stability of the phosphorescent dopant and thus the luminous efficiency of the EL. However, as academically known, Alq₃ has the energy of the triplet excited state that is less than the energy of the triplet excited state of the phosphorescent dopant PtOEP. Therefore, the disclosed OLED is not a dual host OLED that require the energy of the triplet excited state of each of the two light emitting materials be greater than the energy of the triplet excited state of the phosphorescent dopant. Additionally, for operation of the OLED, the concentration rate of the doped phosphorescent dopant is proposed to be greater than 6% by weight in the EL.

Therefore, a heretofore unaddressed need exists in the art to address the aforementioned deficiencies and inadequacies.

### SUMMARY OF THE INVENTION

The present invention, in one aspect, relates to an organic light emitting device comprising a light emitting layer. In one embodiment, the light emitting layer includes an asymmetrically organometallic chelating complex in the amount of A by weight, a polyamine compound having the chemical formula containing two or more tertiaryamines in the amount of B by weight, and a phosphorescent material in the amount of C by weight, where A, B and C satisfy C≦5% and C<A+B. In one embodiment, C is in a range of about 0.1% to about 5% by weight and the sum of A and B is in a range of about 95% to about 99.9% by weight.

The asymmetrically organometallic chelating complex comprises an organometallic chelating complex having a central metal ion and a plurality of organic fragments bonded to the central metal ion, wherein the plurality of organic fragments comprise two or more types of organic fragments. The central metal ion comprises an ion of a metal selected from the groups of metals in the periodic table of the chemical elements, preferably from the IIIA group of metals. In one embodiment, the asymmetrically organometallic chelating complex comprises one of SAlq, AlMq₂OH, PAlq, and BAlq. In one embodiment, the polyamine compound is a hole transporting material. The polyamine compound in another embodiment is an electron transporting material. The phosphorescent material is capable of emitting light at a wavelength in a range of about 450 nm to about 800 nm.

In another aspect, the present invention relates to an organic light emitting device. In one embodiment, the organic light emitting device includes a light emitting layer, where the light emitting layer comprises a first material having a triplet excited state with an energy level, E1, a second material having a triplet excited state with an energy level, E2, and a phosphorescent dopant having a triplet excited state with an energy level, E3, where the first material, the second material and the phosphorescent dopant are chemically and structurally distinct from each other such that E1≧E2>E3.

In one embodiment, the first material includes an organometallic chelating complex in the amount of A by weight. The second material includes a polyamine compound having the chemical formula containing two or more tertiaryamines in the amount of B by weight. The phosphorescent dopant includes a phosphorescent material in the amount of C by weight, and where C<A+B. In one embodiment, C is in a range of about 0.1% to about 5% by weight and the sum of A and B is in a range of about 95% to about 99.9% by weight.

The organometallic chelating complex has a central metal ion and a plurality of organic fragments bonded to the central metal ion. The central metal ion comprises an ion of a metal selected from the groups of metals in the periodic table of the chemical elements, preferably the IIIA group of metals. In one embodiment, the plurality of organic fragments comprises one type of organic fragments. In another embodiment, the plurality of organic fragments comprises two or more types of organic fragments.

In yet another aspect, the present invention relates to a light emitting layer for an organic light emitting device. In one embodiment, the light emitting layer has a first material having a triplet excited state with an energy level, E1. The first material includes an organometallic chelating complex in the amount of A by weight. The organometallic chelating complex has a central metal ion and a plurality of organic fragments bonded to the central metal ion. The central metal ion comprises an ion of a metal selected from the groups of metals in the periodic table of the chemical elements, preferably the IIIA group of metals. The plurality of organic fragments contains one type of organic fragments, or two or more types of organic fragments.

The light emitting layer further has a second material having a triplet excited state with an energy level, E2, and a phosphorescent dopant having a triplet excited state with an energy level, E3. The second material includes a polyamine compound having the chemical formula containing two or more tertiaryamines in the amount of B by weight. The phosphorescent dopant includes a phosphorescent material in the amount of C by weight.

The first material, the second material and the phosphorescent dopant are chemically and structurally distinct from each other such that E1≧E2>E3. Additionally, A, B and C satisfy C<A+B. In one embodiment, C is in a range of about 0.1% to about 5% by weight and the sum of A and B is in a range of about 95% to about 99.9% by weight.

In a further aspect, the present invention relates to a method of manufacturing an organic light emitting device. In one embodiment, the method comprises the step of fabricating a light emitting layer that includes a first material having a triplet excited state with an energy level, E1, a second material having a triplet excited state with an energy level, E2, and a phosphorescent dopant having a triplet excited state with an energy level, E3, where the first material, the second material and the phosphorescent dopant are chemically and structurally distinct from each other such that E1≧E2>E3.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 shows chemical formulae of SAlq, AlMq₂OH, PAlq and BAlq.

FIG. 2 shows chemical formulae of representative polytertiaryamine compounds: (a) having hole transporting ability, and (b) having electron transporting ability.

FIG. 3 shows schematically an energy distribution of the light emitting materials and the phosphorescent dopant of an organic light emitting device according to one embodiment of the present invention.

FIG. 4 shows schematically an energy distribution of the light emitting materials and the phosphorescent dopant of an organic light emitting device and corresponding transitions according to one embodiment of the present invention.

FIG. 5 shows graphs of (a) the luminance as a function of the applied voltage and (b) the current density as a function of the applied voltage for an organic light emitting device according to one embodiment of the present invention.

FIG. 6 shows graphs of (a) the luminance yield as a function of the luminance of and (b) the power efficiency as a function of the luminance for the organic light emitting device used in FIG. 5.

FIG. 7 shows graphs of (a) the CIEx as a function of the luminance and (b) the CIEy as a function of the luminance for the organic light emitting device used in FIG. 5.

FIG. 8 shows graphs of (a) the luminance as a function of the operation time and (b) the voltage as a function of the operation time for the organic light emitting device used in FIG. 5.

FIG. 9 shows a graph of the luminance as a function of the operation time for the organic light emitting device used in FIG. 5.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Additionally, some terms used in this specification are more specifically defined below.

As used herein, the term “polytertiaryamine compound” refers to a polyamine compound having the chemical formula containing two or more tertiaryamines.

The term, as used herein, “electron transporting material” refers to a charge carrying material for which charge transport is predominantly electron transport.

As used herein, the term “hole transporting material” refers to a charge carrying material for which charge transport is predominantly hole transport.

Short names and/or abbreviations used herein, “SAlq” refers to aluminum(III)bis(2-methyl-8-quinolinato); “AlMq2OH” refers to bis(2-methyl-8-quinolinolato)aluminum(III) hydroxide complex; “PAlq” refers to aluminum(III)bis(2-methyl-8-quinolinato)4-phenolate; “BAlq” stands for bis-(2-methyl-8-quinolinolato)-4-(phenyl-phenolato)-aluminium(III); “Alq₃” represents tris(8-hydroxyquinoline) aluminum; “BPhen” refers to 4,7-diphenyl-1,10-phenathroline; “BCP” stands for 2,9-dimethyl-4,7-diphenyl-1,10-phenathroline; “TBPI” refers to 2,2′,2″-(1,3,5-benzinetriyl)-tris(1-phenyl-1-H-benzimidazole); “NPB” stands for N,N′-bis(naphthalene-1-yl)-N,N′-bis(phenyl)-benzidine; “NT2” refers to N,N,N′,N′-Tetrakis(naphth-2-yl)benzidine; “PtOEP” refers to 2,3,7,8,12,13,17,18-Octaethyl-21H,23H-porphine platinum (II); “(Btp₂Ir(acac))” refers to bis(2-(2′-benzo[4,5-a]thienyl)pyridinato-N,C3′)iridium(acetylacetonate); “DCM2” stands for [2-methyl-6-[2,3,6,7-tetrahydro-1H,5H-benzo[ij]quinolizin-9-yl)ethenyl]-4H-pyran-4-ylidene]propane-dinitrile; “Eu-BDBBM” refers to tris(biphenoylmethane) mono(phenanthroline)europium (III); and “Eu-BA” stands for tris(benzoylacetonato)-mono(phenanthroline)europium (III).

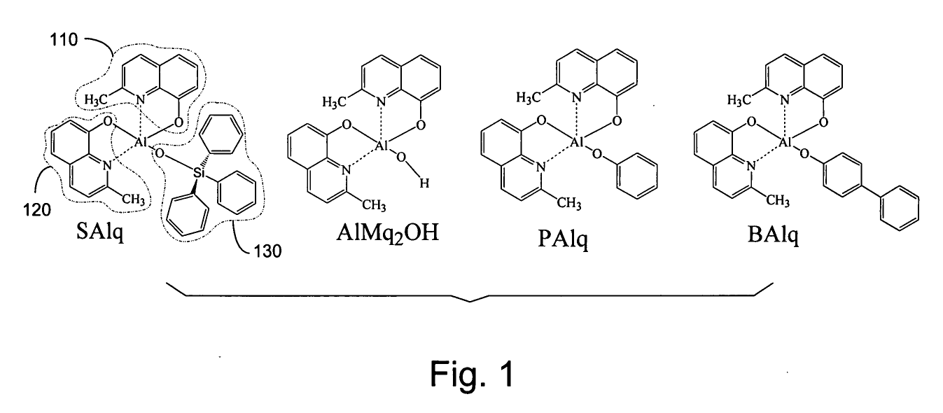

The description will be made as to the embodiments of the present invention in conjunction with the accompanying drawings in FIGS. 1-9. In accordance with the purposes of this invention, as embodied and broadly described herein, this invention, in one aspect, relates to an organic light emitting device with reduced phosphorescent dopant concentrations.

The organic light emitting device comprises a light emitting layer. In one embodiment, the light emitting layer is formed with at least three different materials: an asymmetrically organometallic chelating complex, a polytertiaryamine compound, and a phosphorescent material. The concentrations of the asymmetrically organometallic chelating complex and the polytertiaryamine compound are in the amounts of A and B, respectively, by weight and predominant in the light emitting layer. The phosphorescent material has a concentration in the amount of C by weight and is doped in the light emitting layer. Thus C is much less than the sum of A and B. In one embodiment, the concentration A of the asymmetrically organometallic chelating complex is greater than the concentration B of the polytertiaryamine compound. The sum of A and B is in a range of about 95% to about 99.9% by weight, while C is in a range of about 0.1% to about 5% by weight.

The asymmetrically organometallic chelating complex comprises an organometallic chelating complex having a central metal ion and a plurality of organic fragments bonded to the central metal ion, where the plurality of organic fragments comprise two or more types of organic fragments. The central metal ion includes an ion of a metal selected from the groups of metals in the periodic table of the chemical elements, preferably from the IIIA group of metals such as Al, Ga, In, and so on. The asymmetrically organometallic chelating complex can be a hole transporting material or an electron transporting material. FIG. 1 shows chemical formulae of several exemplary asymmetrically organometallic chelating complexes, such as, SAlq, AlMq₂OH, PAlq, and BAlq. For example, SAlq has a central metal ion of aluminum (Al) and three organic fragments 110, 120 and 130 that are bonded to the Al ion, as shown in FIG. 1. The organic fragments 110 and 120 are chemically and structurally same, while the organic fragment 130 is substantially different from the organic fragments 110 and 120.

According to the embodiment of the present invention, the asymmetrically organometallic chelating complex acts as a host material of the light emitting layer for hosting recombinations of the migrated holes and electrons therein. The host material has the highest concentration in the light emitting layer and serves to cause carriers to be recombined in the host molecule and to transfer the excitation energy to the phosphorescent dopant, thereby making the phosphorescent dopant emit light when both electrodes are energized. Additionally, it is demanded of the host material to be resistant to crystallization and to be a stable compound which is scarcely changed chemically after the layer is formed.

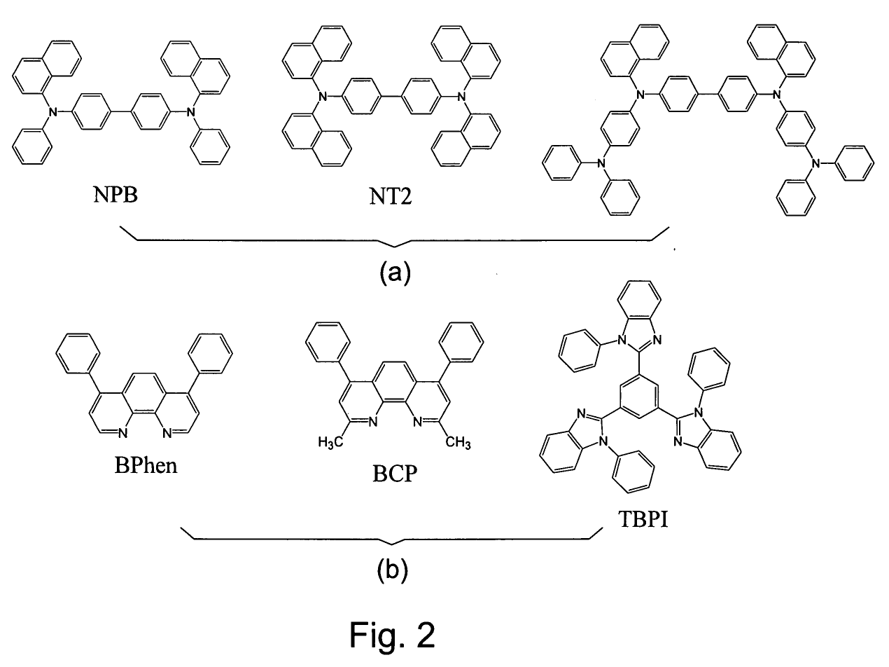

The polytertiaryamine compound comprises a polyamine compound having the chemical formula containing two or more tertiaryamines. FIG. 2 shows chemical structures of exemplary polytertiaryamine compounds, which are corresponding to hole transporting materials, such as NPB, NT2, etc. as shown in FIG. 2a, or electron transporting materials, such as BPhen, BCP and TBPI, as shown in FIG. 2b.

The polytertiaryamine compound acts as an assist material to the host material (asymmetrically organometallic chelating complex) to promote the carrier (holes and electrons) mobility of the host material and the injection and transfer of carriers into the light emitting layer, thereby enhancing the probability of carrier recombination and the luminous efficacy. Additionally, the polytertiaryamine compound may also acts as an additional host material to host the combinations of holes and electrons in a light emitting layer, thereby forming excitons therein. Accordingly the invented OLED device may correspond to a dual host OLED device.

Preferably, the asymmetrically organometallic chelating complex and the polytertiaryamine compound are selected such that when the asymmetrically organometallic chelating complex is an electron transfer material, the polytertiaryamine compound is a hole transfer material, and versus visa. A hole transfer material and an electron transfer material having contrary properties are made to coexist in the light emitting layer to thereby allow the light emitting layer itself to be bipolar, namely to have the ability to transfer both types of carriers, which enhances the probability of recombination and improves luminous efficacy in the light emitting layer.

According to the present invention, light emission from the invented OLED is typically via phosphorescence that occurs during energy transferring from the triplet excited state of the host material to the triplet excited state of the phosphorescent dopant. When an electron and hole localize on the same molecule, an exciton is formed. Recombination of this short-lived state may be visualized as an electron dropping from its conduction potential to a valence band, with relaxation occurring via a photoemissive mechanism. The advantage of phosphorescence is that all excitons that are formed by the recombination of holes and electrons in a light emitting layer may participate in energy transfer and luminescence in certain electroluminescent materials. In general, energy transfer of triplets from a host material to a phosphorescent dopant material typically occurs by diffusion of excitons to neighboring molecules, which may take a long period of time. Accordingly, the phosphorescing process is not an instant process, but takes a long period of time. For conventional OLED devices, the concentration of the phosphorescent dopant material must be greater than about 5% by weight in the light emitting layer so as to have better performance. However, according to embodiments of the present invention, the concentration of the phosphorescent material doped into the light emitting layer can be reduced to be less than about 5% by weight in the light emitting layer, due to the specific energy and chemical structures of the asymmetrically organometallic chelating complex and the polytertiaryamine compound forming the light emitting layer. This would significantly reduce the manufacturing cost of OLED display panels. Furthermore, as shown below, the invented OLED device has better performance compared to a conventional OLED device.

Examples of such a phosphorescent dopant material includes, but not limited to, (Btp₂Ir(acac)), Eu-BDBBM, Eu-BA and DCM2.

To practice the current invention, any type of the phosphorescent materials that accepts excitation energy from the host molecule and is then excited and deactivated to emit light can be employed. Preferably, the phosphorescent material doped into the light emitting layer is selected for emitting light at a wavelength in a range of about 450 nm to about 800 nm.

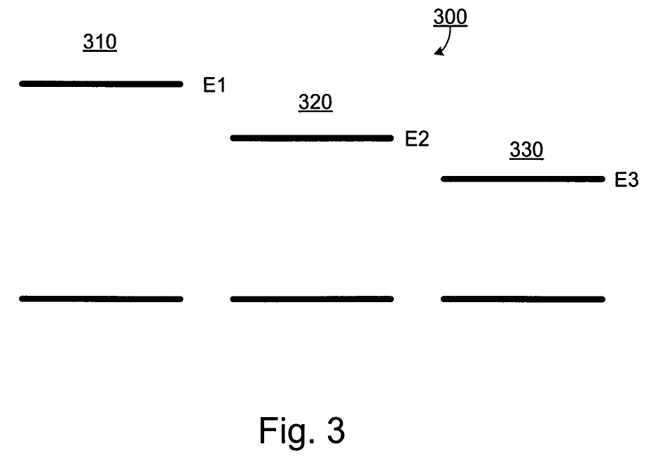

Referring to FIG. 3, energy structures of a light emitting layer for an organic light emitting device is shown according one embodiment of the present invention. The light emitting layer 300 comprises a first material 310 having a triplet excited state with an energy level, E1, a second material 320 having a triplet excited state with an energy level, E2, and a phosphorescent dopant 330 having a triplet excited state with an energy level, E3. The first material 310, the second material 320 and the phosphorescent dopant 330 are chemically and structurally distinct from each other such that E1≧E2>E3.

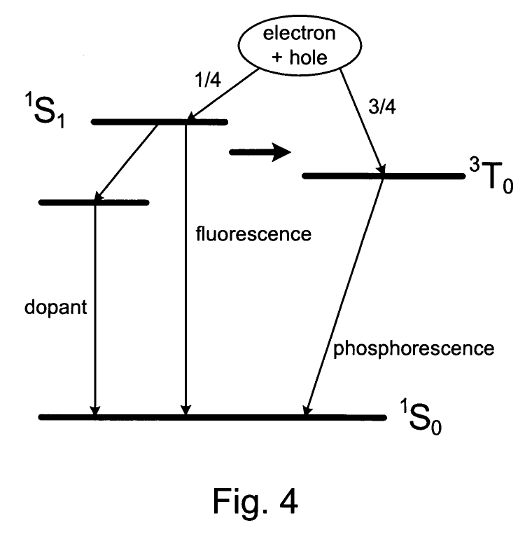

Light emission from OLEDs is typically via fluorescence or phosphorescence. Referring to FIG. 4, when an exciton, formed by the recombination of holes and electrons in the light emitting layer, relaxes from a singlet excited state ¹S₁ to a ground state ¹S₀ of an organic molecule, fluorescence occurs. While an exciton relaxes from a triplet excited state ³T₀ to the ground state ¹S₀ of the organic molecule, phosphorescence occurs. Successful utilization of phosphorescence holds enormous promise for organic electroluminescent devices. For example, an advantage of phosphorescence is that all excitons, which are formed either as a singlet or triplet excited states, may participate in luminescence. This is because the lowest singlet excited state of an organic molecule is typically at a slightly higher energy than the lowest triplet excited state. This means that, for typical phosphorescent compounds, the lowest singlet excited state may rapidly decay to the lowest triplet excited state from which the phosphorescence is produced. In contrast, only a small percentage (about 25%) of excitons in a fluorescent OLED device is capable of producing the fluorescent luminescence that is obtained from a singlet excited state. The remaining excitons in the fluorescent OLED device, which are produced in the lowest triplet excited state of an organic molecule, are typically not capable of being converted into the energetically unfavorable higher singlet excited states from which the fluorescence is produced. This energy, thus, becomes lost to radiationless decay processes that only tend to heat-up the device.

In one embodiment, the first material may include an organometallic chelating complex that a central metal ion and a plurality of organic fragments bonded to the central metal ion. The central metal ion includes an ion of a metal selected from the groups of metals in the periodic table of the chemical elements, preferably the IIIA group of metals. The plurality of organic fragments can be one type of organic fragments, or two or more types of organic fragments. The former is corresponding to a symmetrically organometallic chelating complex while the latter is corresponding to an asymmetrically organometallic chelating complex, as shown in FIG. 1.

The second material includes a polyamine compound having the chemical formula containing two or more tertiaryamines, as shown in FIG. 2.

In one embodiment, the first material is predominant by weight in the light emitting layer and serves a host material to host the recombination of the holes and electrons in the light emitting layer. The second material has a concentration less than that of the first material and serves to promote the hole and electron mobility of the host material and the injection and transfer of holes and electrons into the light emitting layer, thereby enhancing the probability of hole and electron recombination and the luminous efficacy. The second material may also acts as an additional host material to host the combinations of holes and electrons in a light emitting layer.

Each of the first material and the second material can be a hole electron transporting material. Preferably, one of the first material and the second material is an electron transporting material and the other of the first material and the second material is a hole transporting material.

The phosphorescent dopant material is doped into the light emitting layer and has a concentration that is much less than the concentrations of the first and second materials.

Another aspect of the present invention provides a method of manufacturing an organic light emitting device. The method includes the step of fabricating a light emitting layer as disclosed above.

Without intent to limit the scope of the invention, characterizations of an OLED device according to one embodiment of the present invention are described below.

In practice, the OLED device may also have a substrate composed of, for example, glass, polymer, wafer, ceramics, or others, an anode formed on the substrate and typically composed of a transparent conductor, for example, indium tin oxide (ITO), aluminum zinc (AZO), or the like, a hole injection layer formed on the anode, and a hole transporting layer deposited on the injection layer. The OLED device further includes an invented light emitting layer formed on the hole transporting layer, an electron transporting layer deposited on the invented light emitting layer, and a cathode formed on the electron transporting layer. The cathode is typically made of a low work function metal, metal alloy, or combinations thereof. During operation, an electric field is applied between the anode and cathode and causes positive charges (holes) and negative charges (electrons) to be respectively injected from the anode and the cathode to recombine in the invented light emitting layer and thereby produce light emission.

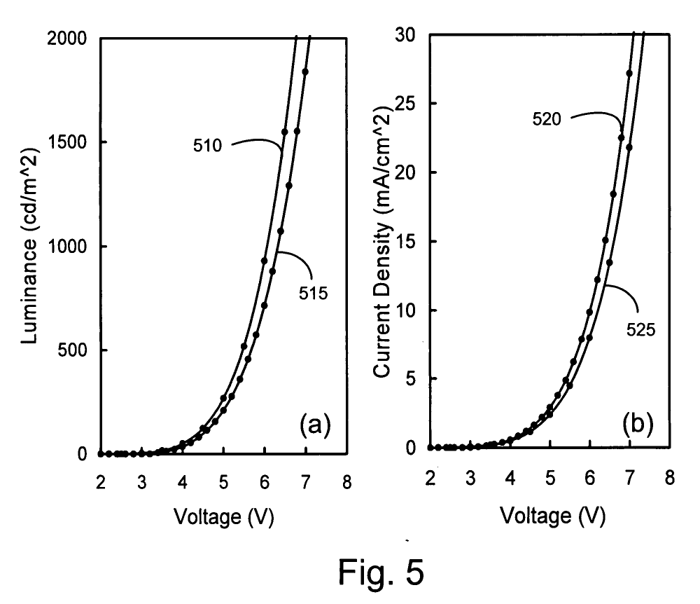

Referring to FIGS. 5-9, the OLED device has a light emitting layer comprising an asymmetrically organometallic chelating complex, BAlq, at a concentration of about 90% by weight, a ploytertiaryamine, N,N,N′,N′-TETRAKIS(NAPHTH-2-YL)BENZIDINE, at a concentration of about 10% by weight and a phosphorescent dopant material, (Btp₂Ir(acac)) at a concentration of about 2% by weight, according to one embodiment of the present invention. As comparisons, an OLED device having a conventional light emitting layer that includes only BAlq at a concentration of about 90% by weight and (Btp₂Ir(acac)) at a concentration of about 12% is employed.

FIG. 5 shows the luminance 510 and the current density 520 as a function of the applied voltage for the invented OLED device. In the figure, the luminance 515 and the current density 525 for the conventional OLED device is shown. It is concluded that to achieve specific values of the luminance and the current density, the invented OLED device needs a lower applied voltage than what the conventional OLED device may need.

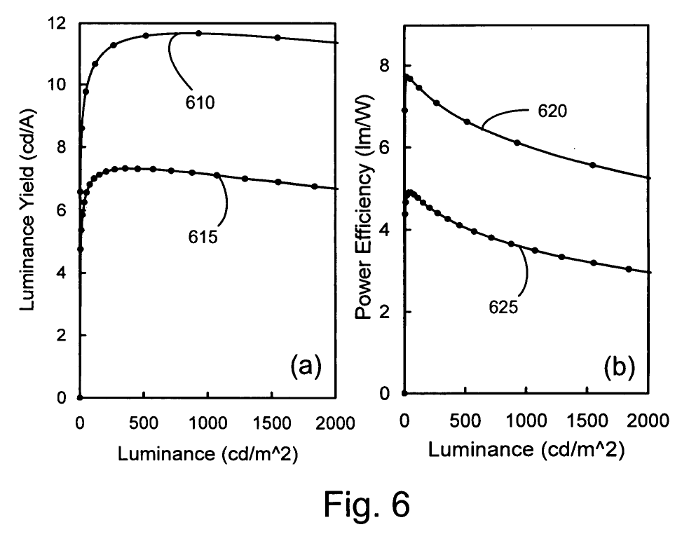

As shown in FIG. 6, the luminance yield 610 and 615 and the power efficiency 620 and 625 are for the invented OLED device and conventional OLED device, respectively. The luminous efficiency of the invented OLED device increases about 150%, comprising to that of the conventional OLED device.

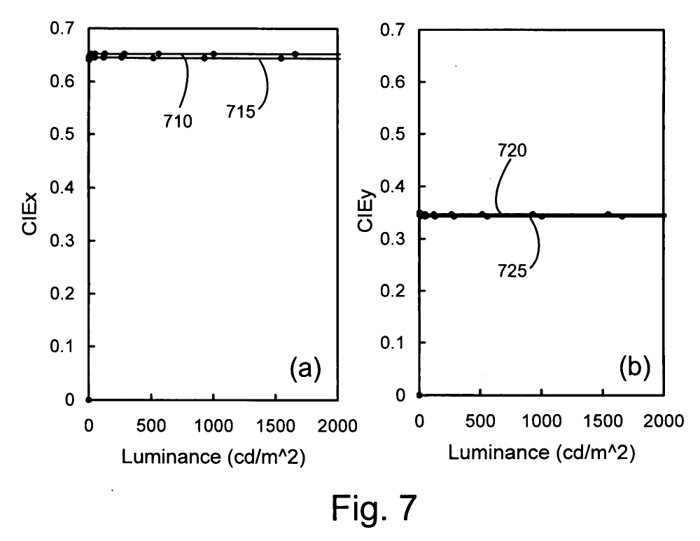

FIG. 7 is the CIEx (710 and 715) and the CIEy (720 and 725) as a function of the luminance for the invented OLED device and conventional OLED device, respectively.

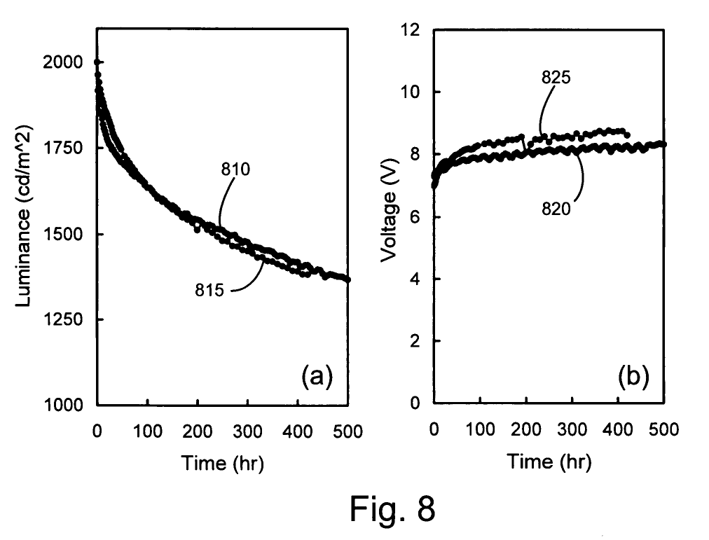

FIG. 8 shows the luminance (810 and 815) and the voltage (820 and 825) as a function of the operation time at the temperature of about 25° C. for the invented OLED device and conventional OLED device, respectively. It is clearly demonstrated that the invented OLED device operates longer and at lower voltages over the conventional OLED device.

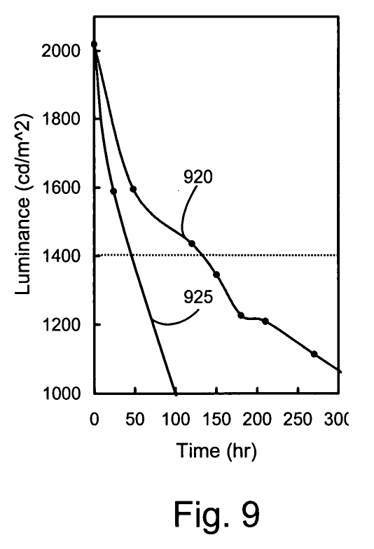

FIG. 9 shows the luminance (920 and 925) as a function of the operation time at the temperature of about 70° C. for the invented OLED device and conventional OLED device, respectively. Again, it shows that the invented OLED device has great advantages to the conventional OLED device, particularly in terms of lifetime, operating voltage, luminous efficiency and stability of the device. Furthermore, the invented OLED device requires less amount of a phosphorescent dopant material to be doped into the light emitting layer, which could reduce significantly the material cost of the OLED device.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An organic light emitting device, comprising a light emitting layer, wherein the light emitting layer comprises:
a. an asymmetrically organometallic chelating complex in the amount of A by weight;
b. a polyamine compound having the chemical formula containing two or more tertiaryamines in the amount of B by weight; and
c. a phosphorescent material in the amount of C by weight,
wherein A, B and C satisfy C≦5% and C<A+B.

2. The organic light emitting device of claim 1, wherein C is in a range of about 0.1% to about 5% by weight and the sum of A and B is in a range of about 95% to about 99.9% by weight.

3. The organic light emitting device of claim 1, wherein the asymmetrically organometallic chelating complex comprises an organometallic chelating complex having a central metal ion and a plurality of organic fragments bonded to the central metal ion, wherein the plurality of organic fragments comprise two or more types of organic fragments.

4. The organic light emitting device of claim 3, wherein the central metal ion comprises an ion of a metal selected from the groups of metals in the periodic table of the chemical elements, preferably from the IIIA group of metals.

5. The organic light emitting device of claim 4, wherein the asymmetrically organometallic chelating complex comprises one of SAlq, AlMq₂OH, PAlq, and BAlq.

6. The organic light emitting device of claim 1, wherein the polyamine compound is a hole transporting material.

7. The organic light emitting device of claim 1, wherein the polyamine compound is an electron transporting material.

8. The organic light emitting device of claim 1, wherein the phosphorescent material is capable of emitting light at a wavelength in a range of about 450 nm to about 800 nm.

9. An organic light emitting device, comprising a light emitting layer, wherein the light emitting layer comprises:
a. a first material having a triplet excited state with an energy level, E1;
b. a second material having a triplet excited state with an energy level, E2; and
c. a phosphorescent dopant having a triplet excited state with an energy level, E3, wherein the first material, the second material and the phosphorescent dopant are chemically and structurally distinct from each other such that E1≧E2>E3.

10. The organic light emitting device of claim 9, wherein the first material comprises an organometallic chelating complex in the amount of A by weight.

11. The organic light emitting device of claim 10, wherein the organometallic chelating complex comprises a central metal ion and a plurality of organic fragments bonded to the central metal ion.

12. The organic light emitting device of claim 11, wherein the central metal ion comprises an ion of a metal selected from the groups of metals in the periodic table of the chemical elements, preferably the IIIA group of metals.

13. The organic light emitting device of claim 11, wherein the plurality of organic fragments comprise one type of organic fragments.

14. The organic light emitting device of claim 11, wherein the plurality of organic fragments comprise two or more types of organic fragments.

15. The organic light emitting device of claim 10, wherein the second material comprises a polyamine compound having the chemical formula containing two or more tertiaryamines in the amount of B by weight.

16. The organic light emitting device of claim 15, wherein the phosphorescent dopant comprises a phosphorescent material in the amount of C by weight, and wherein C<A+B.

17. The organic light emitting device of claim 16, wherein C is in a range of about 0.1% to about 5% by weight and the sum of A and B is in a range of about 95% to about 99.9% by weight.

18. A light emitting layer for an organic light emitting device, comprises:
a. a first material having a triplet excited state with an energy level, E1;
b. a second material having a triplet excited state with an energy level, E2; and
c. a phosphorescent dopant having a triplet excited state with an energy level, E3, wherein the first material, the second material and the phosphorescent dopant are chemically and structurally distinct from each other such that E1≦E2>E3.

19. The organic light emitting device of claim 18, wherein the first material comprises an organometallic chelating complex in the amount of A by weight.

20. The organic light emitting device of claim 19, wherein the organometallic chelating complex comprises a central metal ion and a plurality of organic fragments bonded to the central metal ion.

21. The organic light emitting device of claim 20, wherein the central metal ion comprises an ion of a metal selected from the groups of metals in the periodic table of the chemical elements, preferably the IIIA group of metals.

22. The organic light emitting device of claim 20, wherein the plurality of organic fragments comprise one type of organic fragments.

23. The organic light emitting device of claim 20, wherein the plurality of organic fragments comprise two or more types of organic fragments.

24. The organic light emitting device of claim 19, wherein the second material comprises a polyamine compound having the chemical formula containing two or more tertiaryamines in the amount of B by weight.

25. The organic light emitting device of claim 24, wherein the phosphorescent dopant comprises a phosphorescent material in the amount of C by weight, and wherein C<A+B.

26. The organic light emitting device of claim 25, wherein C is in a range of about 0.1-5% by weight and the sum of A and B is in a range of about 95% to about 99.9% by weight.

27. A method of manufacturing an organic light emitting device, comprising the step of fabricating a light emitting layer having
a. a first material having a triplet excited state with an energy level, E1;
b. a second material having a triplet excited state with an energy level, E2; and
c. a phosphorescent dopant having a triplet excited state with an energy level, E3, wherein the first material, the second material and the phosphorescent dopant are chemically and structurally distinct from each other such that E1≧E2>E3.

28. The method of claim 27, wherein the first material comprises an organometallic chelating complex in the amount of A by weight.

29. The method of claim 28, wherein the organometallic chelating complex comprises a central metal ion and a plurality of organic fragments bonded to the central metal ion.

30. The method of claim 29, wherein the central metal ion comprises an ion of a metal selected from the groups of metals in the periodic table of the chemical elements, preferably the IIIA group of metals.

31. The method of claim 29, wherein the plurality of organic fragments comprise one type of organic fragments.

32. The method of claim 29, wherein the plurality of organic fragments comprise two or more types of organic fragments.

33. The method of claim 28, wherein the second material comprises a polyamine compound having the chemical formula containing two or more tertiaryamines in the amount of B by weight.

34. The method of claim 33, wherein the phosphorescent dopant comprises a phosphorescent material in the amount of C by weight, and wherein C<A+B.

35. The method of claim 34, wherein C is in a range of about 0.1% to about 5% by weight and the sum of A and B is in a range of about 95% to about 99.9% by weight.
